(19) United States
(12) Patent Application Publication
(10) Pub. No.: US 2023/0223096 A1
(43) Pub. Date: Jul. 13, 2023

(54) CONFIGURABLE ECC MODE IN DRAM

(71) Applicant: Intel Corporation, Santa Clara, CA (US)

(72) Inventors: Kuljit S. BAINS, Olympia, WA (US); Christopher P. MOZAK, Portland, OR (US); Sagar SUTHRAM, Portland, OR (US); Randy B. OSBORNE, Beaverton, OR (US)

(21) Appl. No.: 18/122,038

(22) Filed: Mar. 15, 2023

(51) Int. Cl. G11C 29/42; G11C 29/46; G11C 29/12

(52) U.S. Cl. CPC G11C 29/42; G11C 29/46; G11C 29/1201

(57) ABSTRACT

Methods and apparatus for configurable ECC (error correction code) mode in DRAM. Selected memory cells in the bank arrays of a DRAM device (e.g., die) are used to store ECC bits. A DRAM device (e.g., die) is configured to operate in a first mode in which an on-die ECC engine employs selected bits in the arrays of memory cells in the DRAM banks as ECC bits to perform ECC operations and to operate in a second mode under which the ECC bits are not employed for ECC operations by the ECC engine and made available for external use by a host. In the second mode, the repurposed ECC bits may comprise RAS bits used for RAS (Reliability, Serviceability, and Availability) operations and/or metabits comprising metadata used for other operations by the host.

### BACKGROUND INFORMATION

For the better part of three decades processor and memory performance generally scaled in accordance with Moore's law, where the fundamental performance improvements were obtained via increases in the number of transistors (enabled through decreases in feature size and larger dies) and increases in frequency. Eventually, Moore's law hit limitations relating to feature size and frequency. These limitations have been addressed on the processor side by adding more cores, on-chip or off-chip accelerators, Graphic Processor Units (GPUs) and various other approaches that increase the number and efficiency of compute elements. However, increasing memory performance has been more difficult, as there are practical limits to frequency and scaling the number of channels is limited when using conventional package technologies under which a processor or System on a Chip (SoC) with integrated memory controller(s) is coupled to memory devices (e.g., Dynamic Random Access Memory (DRAM) Dual Inline Memory Modules (DIMMs)) using wiring implemented in printed circuit boards coupled to pins or solder pads on the processor/SOC.

One approach that is gaining traction is the use of three-dimensional (3D) integration of DRAM above and/or below compute dies, including stacked die structures and packages, such as processor-in-memory (PIM) modules. (PIM modules may also be called compute on memory modules or compute near memory modules.) In a PIM module (which are sometimes called PIM chips when the stacked die structures are integrated on the same chip), the processor or CPU and stacked memory structures are combined in the same chip or package.

Error correction of data retrieved from a memory that includes volatile types of memory such as, but not limited to, DRAM memory may include use of an error correction code (ECC) scheme. The ECC scheme may include use of ECC encoded codewords to protect data or recover from errors related to data retrieved or read from the memory. ECC encoded data read from the memory may be able to identify and correct a given number of errors (e.g., bit errors). Also, various additional protections for ECC schemes may be implemented to further protect data or recover from errors.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a diagram illustrating selective elements in a memory subsystem including a memory controller coupled to a DIMM showing two ranks of DRAM devices;

FIG. 2 is a schematic diagram of a DRAM memory structure;

FIG. 3 is a schematic diagram illustrating an example system including a processor/SoC and elements of a memory subsystem;

FIG. 4 is a diagram illustrating two view of a DRAM die structure;

FIG. 5 is a diagram illustrating a DRAM die that implements a respective ECC engine per bank group;

FIG. 6 is a diagram illustrating a DRAM die that implements a single ECC engine configured to perform ECC testing across all banks in the DRAM die, according to one embodiment;

FIG. 7 is a schematic diagram of a system including an SoC with an integrated memory controller having two memory channels coupled to a multiple DRAM dies configured in a manner similar to that shown in FIG. 6, according to one embodiment;

FIG. 8a shows a logical representation and a physical representation of a sub word-line (SWL) in which 128 bits of data and 8 or 16 ECC bits are stored, according to one embodiment;

FIG. 8b shows a logical representation and a physical representation of a pair of SWLs in which 128 bits of data and 4 or 8 ECC bits are stored, according to one embodiment;

FIG. 9 shows a logical representation and a physical representation of an SWL in which 128 bits of data, a first set of 8 ECC bits, and a second set of 8 or 16 ECC bits are stored, according to one embodiment;

FIG. 10a shows a logical representation of 64 Bytes of data and 16 ECC bits that are repurposed as 16 RAS bits used for SEC-DEC error detection at runtime, according to one embodiment;

FIG. 10b shows a logical representation of 64 Bytes of data and 16 ECC bits that are repurposed as 10 RAS bits used and 6 metabits during runtime, according to one embodiment;

FIG. 11 is a flowchart illustrating operations performed during test and/or integration by a single on-die ECC engine when operating in a first mode, according to one embodiment;

FIG. 12a is a diagram illustrating an example of a PIM module;

FIG. 12b shows further details of the structure of a PIM module;

FIG. 12c shows another example of a PIM module including a CPU or XPU coupled to DRAMs in a stacked 3D structure; and

FIG. 12d shows a variant of the PIM module of FIG. 8c where there are one or more layers of DRAM dies stacked above and below the CPU or XPU.

### DETAILED DESCRIPTION

Embodiments of methods and apparatus for configurable ECC mode in DRAM are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

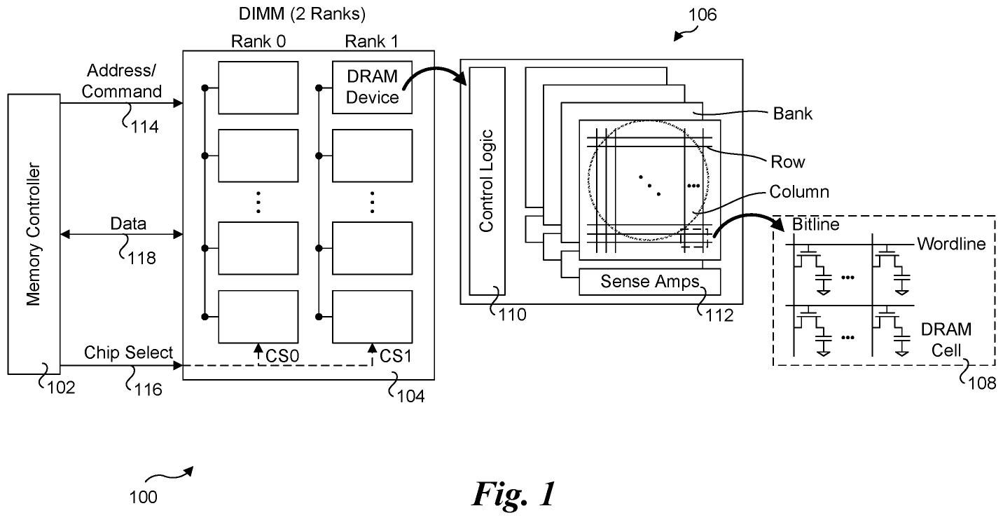

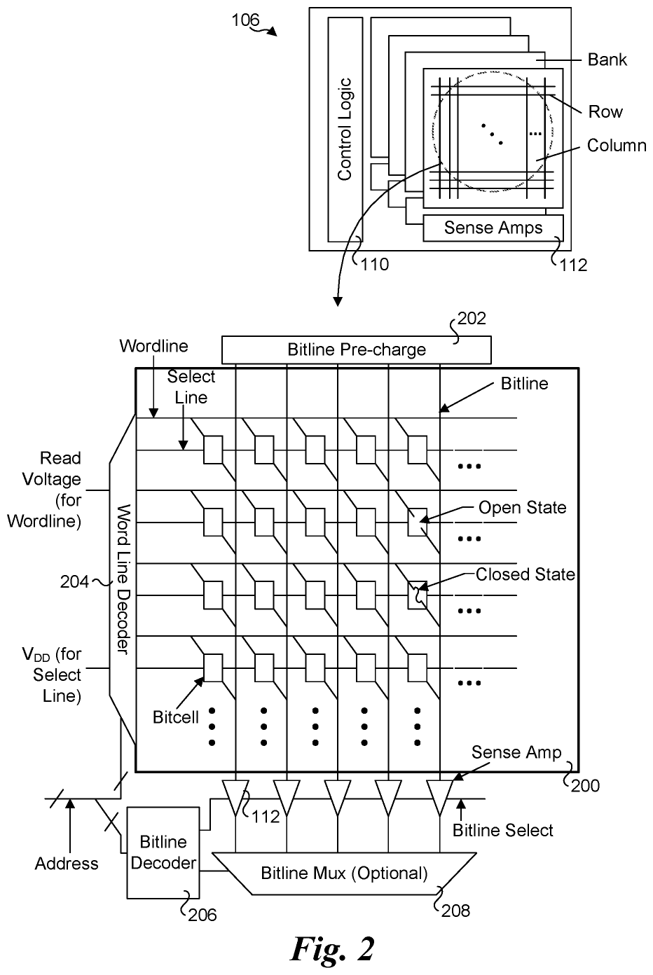

To better understand aspects of the teachings and principles of the embodiments disclosed herein, a brief primer on the operation of DRAM is provided with reference an exemplary memory subsystem illustrated in FIGS. 1 and 2. As shown in FIG. 1, selective elements of a memory subsystem 100 include a memory controller 102 coupled to a DIMM 104 showing two ranks of DRAM devices 106. Generally, a DRAM DIMM may have one or more ranks. Each DRAM device includes a plurality of banks comprising an array of DRAM cells 108 that are organized (laid out) and as rows and columns. Each row comprises a Wordline (or wordline), while each column comprises a Bitline (or bitline). Each DRAM device 106 further includes control logic 110 and sense amps 112 that are used to access DRAM cells 108.

As further shown in FIG. 1, memory controller provides inputs comprising address/commands 114 and chip select 116. For memory Writes, the memory controller inputs further include data 118 that are written to DRAM cells 108 based on the address and chip select inputs. Similarly, for memory Reads, data 118 stored in DRAM cells 108 identified by the address and chip select inputs is returned to memory controller 102.

As described herein, reference to memory devices (e.g., DRAM devices) can apply to different volatile memory types. Volatile memory is memory whose state (and therefore the data stored on it) is indeterminate if power is interrupted to the device. Dynamic volatile memory requires refreshing the data stored in the device to maintain state. One example of dynamic volatile memory includes DRAM, or some variant such as synchronous DRAM (SDRAM). A memory subsystem as described herein may be compatible with a number of memory technologies or standards, such as DDR3 (double data rate version 3, JESD79-3, originally published by JEDEC (Joint Electronic Device Engineering Council) on Jun. 27, 2007), DDR4 (DDR version 4, JESD79-4, originally published in September 2012 by JEDEC), LPDDR3 (low power DDR version 3, JESD209-3B, originally published in August 2013 by JEDEC), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235, originally published by JEDEC in October 2013), LPDDR5 (originally published by JEDEC in February 2019), HBM2 ((HBM version 2), originally published by JEDEC in December 2018), DDR5 (DDR version 5, originally published by JEDEC in July 2020), or others or combinations of memory technologies, and technologies based on derivatives or extensions of such specifications.

Under conventional (S)DRAM memory, data are generally accessed (Read and Written) using cachelines (also called cache lines) comprising a sequence of memory cells (bits) in a wordline. The cachelines for a given memory architecture generally have a predetermined width or size, such as 64 Bytes, noting other widths/sizes maybe used.

Referring to FIG. 2, the DRAM device 106 structure includes a bank 200 including an array of memory cells called bitcells organized as wordlines and bitlines. A bitcell may have an open state or closed state (or otherwise have a capacitor that is charged or uncharged). A bitline pre-charge 202 and a word inline decoder 204 are coupled to bank 200. A bitline decoder 206 is used for selecting bitlines. An optional bitline mux (multiplexer) 208 may be used to multiplex the outputs of sense amps 112.

To change the logic level for a cell, the cell's transistor is used to charge or discharge the capacitor. A charged capacitor represents a logic high, or ‘1’, while a discharged capacitor represents a logic low, or ‘0’. The charging/discharging is done via the wordline and bitline. During a read or write, the wordline goes high and the transistor connects the capacitor to the bitline. Whatever value is on the bitline (‘1’ or ‘0’) gets stored or retrieved from the capacitor. Thus, to access data in a given row, the wordline for the row is activated (this is also referred to as row activation).

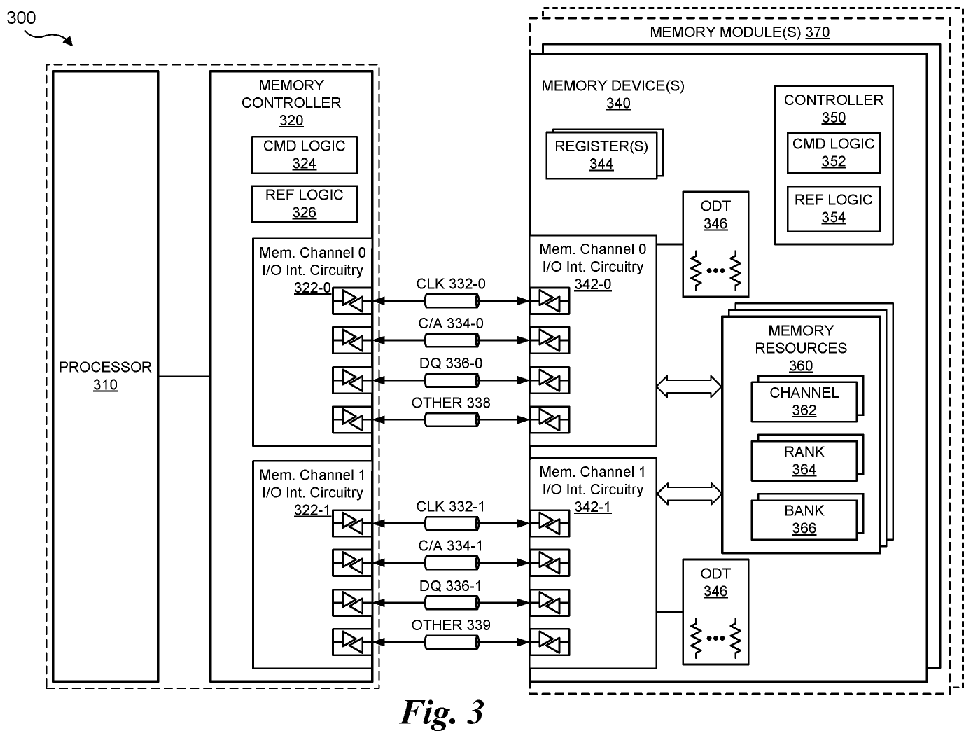

FIG. 3 illustrates an example system 300. In some examples, as shown in FIG. 3, system 300 includes a processor and elements of a memory subsystem in a computing device. Processor 310 represents a processing unit of a computing system that may execute an operating system (OS) and applications, which can collectively be referred to as the host or the user of the memory subsystem. The OS and applications execute operations that result in memory accesses. Processor 310 can include one or more separate processors. Each separate processor may include a single processing unit, a multicore processing unit, or a combination. The processing unit may be a primary processor such as a central processing unit (CPU), a peripheral processor such as a graphics processing unit (GPU), or a combination. Memory accesses may also be initiated by devices such as a network controller or hard disk controller. Such devices may be integrated with the processor in some systems or attached to the processer via a bus (e.g., a PCI express bus), or a combination. System 300 may be implemented as a system on a chip (SoC) or may be implemented with standalone components.

Descriptions herein referring to a “RAM” or “RAM device” can apply to any memory device that allows random access, whether volatile or nonvolatile. Descriptions referring to a “DRAM”, “SDRAM, “DRAM device” or “SDRAM device” may refer to a volatile random access memory device. The memory device, SDRAM or DRAM may refer to the die itself, to a packaged memory product that includes one or more dies, or both. In some examples, a system with volatile memory that needs to be refreshed may also include at least some nonvolatile memory.

Memory controller 320, as shown in FIG. 3, may represent one or more memory controller circuits or devices for system 300. Also, memory controller 320 may include logic and/or features that generate memory access commands in response to the execution of operations by processor 310. In some examples, memory controller 320 may access one or more memory device(s) 340. For these examples, memory device(s) 340 may be SDRAM or DRAM devices in accordance with any referred to above. Memory device(s) 340 may be organized and managed through different channels, where these channels may couple in parallel to multiple memory devices via buses and signal lines. Each channel may be independently operable. Thus, separate channels may be independently accessed and controlled, and the timing, data transfer, command and address exchanges, and other operations may be separate for each channel. Coupling may refer to an electrical coupling, communicative coupling, physical coupling, or a combination of these. Physical coupling may include direct contact. Electrical coupling, for example, includes an interface or interconnection that allows electrical flow between components, or allows signaling between components, or both. Communicative coupling, for example, includes connections, including wired or wireless, that enable components to exchange data.

According to some examples, settings for each channel are controlled by separate mode registers or other register settings. For these examples, memory controller 320 may manage a separate memory channel, although system 300 may be configured to have multiple channels managed by a single memory controller, or to have multiple memory controllers on a single channel. In one example, memory controller 320 is part of processor 310, such as logic and/or features of memory controller 320 are implemented on the same die or implemented in the same package space as processor 310, sometimes referred to as an integrated memory controller.

Memory controller 320 includes Input/Output (I/O) interface circuitry 322 to couple to a memory bus, which is replicated for two memory channels 0 and 1. I/O interface circuitry 322 (as well as I/O interface circuitry 342 of memory device(s) 340) may include pins, pads, connectors, signal lines, traces, or wires, or other hardware to connect the devices, or a combination of these. I/O interface circuitry 322 may include a hardware interface. As shown in FIG. 3, I/O interface circuitry 322 includes at least drivers/transceivers for signal lines. Commonly, wires within an integrated circuit interface couple with a pad, pin, or connector to interface signal lines or traces or other wires between devices. I/O interface circuitry 322 can include drivers, receivers, transceivers, or termination, or other circuitry or combinations of circuitry to exchange signals on the signal lines between memory controller 320 and memory device(s) 340. The exchange of signals includes at least one of transmit or receive. While shown as coupling I/O interface circuitry 322 from memory controller 320 to I/O interface circuitry 342 of memory device(s) 340, it will be understood that in an implementation of system 300 where groups of memory device(s) 340 are accessed in parallel, multiple memory devices can include I/O interface circuitry to the same interface of memory controller 320. In an implementation of system 300 including one or more memory module(s) 370, I/O interface circuitry 342 may include interface hardware of memory module(s) 370 in addition to interface hardware for memory device(s) 340. Other memory controllers 320 may include multiple, separate interfaces to one or more memory devices of memory device(s) 340.

In some examples, memory controller 320 may be coupled with memory device(s) 340 via multiple signal lines. The multiple signal lines may include at least one clock (CLK) 332, command/address (C/A) 334, and write data (DQ) and read data (DQ) 336, and zero or more other signal lines 338. According to some examples, a composition of signal lines coupling memory controller 320 to memory device(s) 340 may be referred to collectively as a memory bus. The signal lines for C/A 334 may be referred to as a “command bus”, a “C/A bus” or a CMD/ADD bus, or some other designation indicating the transfer of commands and/or address data. The signal lines for DQ 336 may be referred to as a “data bus”. As illustrated in FIG. 3, there are respective signals/signal lines for each of memory channel 0 I/O interface circuitry 322-0 and 322-1.

According to some examples, independent channels may have different clock signals, command buses, data buses, and other signal lines. For these examples, system 300 may be considered to have multiple “buses,” in the sense that an independent interface path may be considered a separate bus. It will be understood that in addition to the signal lines shown in FIG. 3, a bus may also include at least one of strobe signaling lines, alert lines, auxiliary lines, or other signal lines, or a combination of these additional signal lines. It will also be understood that serial bus technologies can be used for transmitting signals between memory controller 320 and memory device(s) 340. An example of a serial bus technology is 8B10B encoding and transmission of high-speed data with embedded clock over a single differential pair of signals in each direction. In some examples, C/A 334 represents signal lines shared in parallel with multiple memory device(s) 340. In other examples, multiple memory devices share encoding command signal lines of C/A 334, and each has a separate chip select (CS_n) signal line to select individual memory device(s) 340.

In some examples, the bus between memory controller 320 and memory device(s) 340 includes a subsidiary command bus routed via signal lines included in C/A 334 and a subsidiary data bus to carry the write and read data routed via signal lines included in DQ 336. In some examples, C/A 334 and DQ 336 may separately include bidirectional lines. In other examples, DQ 336 may include unidirectional write signal lines to write data from the host to memory and unidirectional lines to read data from the memory to the host.

According to some examples, in accordance with a chosen memory technology and system design, signals lines included in other 338 may augment a memory bus or subsidiary bus. For example, strobe line signal lines for a DQS. Based on a design of system 300, or memory technology implementation, a memory bus may have more or less bandwidth per memory device included in memory device(s) 340. The memory bus may support memory devices included in memory device(s) 340 that have either a x32 interface, a x16 interface, a x8 interface, or other interface. The convention “xW,” where W is an integer that refers to an interface size or width of the interface of memory device(s) 340, which represents a number of signal lines to exchange data with memory controller 320. The interface size of these memory devices may be a controlling factor on how many memory devices may be used concurrently per channel in system 300 or coupled in parallel to the same signal lines. In some examples, high bandwidth memory devices, wide interface memory devices, or stacked memory devices, or combinations, may enable wider interfaces, such as a x128 interface, a x256 interface, a x512 interface, a x1024 interface, or other data bus interface width.

According to some examples, memory device(s) 340 represent memory resources for system 300. For these examples, each memory device included in memory device(s) 340 is a separate memory die. Separate memory devices may interface with multiple (e.g., 2) channels per device or die. A given memory device of memory device(s) 340 may include I/O interface circuitry 342 and may have a bandwidth determined by an interface width associated with an implementation or configuration of the given memory device (e.g., x16 or x8 or some other interface bandwidth). I/O interface circuitry 342 may enable the memory devices to interface with memory controller 320. I/O interface circuitry 342 may include a hardware interface and operate in coordination with I/O interface circuitry 322 of memory controller 320.

In some examples, multiple memory device(s) 340 may be connected in parallel to the same command and data buses (e.g., via C/A 334 and DQ 336). In other examples, multiple memory device(s) 340 may be connected in parallel to the same command bus but connected to different data buses. For example, system 300 may be configured with multiple memory device(s) 340 coupled in parallel, with each memory device responding to a command, and accessing memory resources 360 internal to each memory device. For a write operation, an individual memory device of memory device(s) 340 may write a portion of the overall data word, and for a read operation, the individual memory device may fetch a portion of the overall data word. As non-limiting examples, a specific memory device may provide or receive, respectively, 8 bits of a 128-bit data word for a read or write operation, or 8 bits or 16 bits (depending for a x8 or a x16 device) of a 256-bit data word. The remaining bits of the word may be provided or received by other memory devices in parallel.

According to some examples, memory device(s) 340 may be disposed directly on a motherboard or host system platform (e.g., a PCB (printed circuit board) on which processor 310 is disposed) of a computing device. Memory device(s) 340 may be organized into memory module(s) 370. In some examples, memory module(s) 370 may represent dual inline memory modules (DIMMs). In some examples, memory module(s) 370 may represent other organizations or configurations of multiple memory devices that share at least a portion of access or control circuitry, which can be a separate circuit, a separate device, or a separate board from the host system platform. In some examples, memory module(s) 370 may include multiple memory device(s) 340, and memory module(s) 370 may include support for multiple separate channels to the included memory device(s) 340 disposed on them.

In some examples, memory device(s) 340 may be incorporated into a same package as memory controller 320. For example, incorporated in a multi-chip-module (MCM), a package-on-package with through-silicon via (TSV), or other techniques or combinations. Similarly, in some examples, memory device(s) 340 may be incorporated into memory module(s) 370, which themselves may be incorporated into the same package as memory controller 320. It will be appreciated that for these and other examples, memory controller 320 may be part of or integrated with processor 310.

As shown in FIG. 3, in some examples, memory device(s) 340 include memory resources 360. Memory resources 360 may represent individual arrays of memory locations or storage locations for data. Memory resources 360 may be managed as rows of data, accessed via wordline (rows) and bitline (individual bits within a row) control. Memory resources 360 may be organized as separate channels 362, ranks 364, and banks of memory 366. Channels may refer to independent control paths to storage locations within memory device(s) 340. Ranks may refer to common locations across multiple memory devices (e.g., same row addresses within different memory devices). Banks may refer to arrays of memory locations within a given memory device of memory device(s) 340. Banks may be divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to access memory resources 360. For example, the same physical memory locations can be accessed over a specific channel as a specific bank, which can also belong to a rank. Thus, the organization of memory resources 360 may be understood in an inclusive, rather than exclusive, manner.

According to some examples, as shown in FIG. 3, memory device(s) 340 include one or more register(s) 344. Register(s) 344 may represent one or more storage devices or storage locations that provide configuration or settings for operation memory device(s) 340. In one example, register(s) 344 may provide a storage location for memory device(s) 340 to store data for access by memory controller 320 as part of a control or management operation. For example, register(s) 344 may include one or more mode registers (MRs) and/or may include one or more multipurpose registers.

In some examples, writing to or programming one or more registers of register(s) 344 may configure memory device(s) 340 to operate in different “modes”. For these examples, command information written to or programmed to the one or more register may trigger different modes within memory device(s) 340. Additionally, or in the alternative, different modes can also trigger different operations from address information or other signal lines depending on the triggered mode. Programmed settings of register(s) 344 may indicate or trigger configuration of I/O settings. For example, configuration of timing, termination, on-die termination (ODT), driver configuration, or other I/O settings.

According to some examples, memory device(s) 340 includes ODT 346 as part of the interface hardware associated with I/O interface circuitry 342. ODT 346 may provide settings for impedance to be applied to the interface to specified signal lines. For example, ODT 346 may be configured to apply impedance to signal lines include in DQ 336 or C/A 334. The ODT settings for ODT 346 may be changed based on whether a memory device of memory device(s) 340 is a selected target of an access operation or a non-target memory device. ODT settings for ODT 346 may affect timing and reflections of signaling on terminated signal lines included in, for example, C/A 334 or DQ 336. Control over ODT setting for ODT 346 can enable higher-speed operation with improved matching of applied impedance and loading. Impedance and loading may be applied to specific signal lines of I/O interface circuitry 342, 322 (e.g., C/A 334 and DQ 336) and is not necessarily applied to all signal lines.

In some examples, as shown in FIG. 3, memory device(s) 340 includes controller 350. Controller 350 may represent control logic within memory device(s) 340 to control internal operations within memory device(s) 340. For example, controller 350 decodes commands sent by memory controller 320 and generates internal operations to execute or satisfy the commands. Controller 350 may be referred to as an internal controller and is separate from memory controller 320 of the host. Controller 350 may include logic and/or features to determine what mode is selected based on programmed or default settings indicated in register(s) 344 and configure the internal execution of operations for access to memory resources 360 or other operations based on the selected mode. Controller 350 generates control signals to control the routing of bits within memory device(s) 340 to provide a proper interface for the selected mode and direct a command to the proper memory locations or addresses of memory resources 360. Controller 350 includes command (CMD) logic 352, which can decode command encoding received on command and address signal lines. Thus, CMD logic 352 can be or include a command decoder. With command logic 352, memory device can identify commands and generate internal operations to execute requested commands.

Referring again to memory controller 320, memory controller 320 includes CMD logic 324, which represents logic and/or features to generate commands to send to memory device(s) 340. The generation of the commands can refer to the command prior to scheduling, or the preparation of queued commands ready to be sent. Generally, the signaling in memory subsystems includes address information within or accompanying the command to indicate or select one or more memory locations where memory device(s) 340 should execute the command. In response to scheduling of transactions for memory device(s) 340, memory controller 320 can issue commands via I/O interface circuitry 322 to cause memory device(s) 340 to execute the commands. In some examples, controller 350 of memory device(s) 340 receives and decodes command and address information received via I/O interface circuitry 342 from memory controller 320. Based on the received command and address information, controller 350 may control the timing of operations of the logic, features and/or circuitry within memory device(s) 340 to execute the commands. Controller 350 may be arranged to operate in compliance with standards or specifications such as timing and signaling requirements for memory device(s) 340. Memory controller 320 may implement compliance with standards or specifications by access scheduling and control.

In some examples, memory controller 320 includes refresh (REF) logic 326. REF logic 326 may be used for memory resources that are volatile and need to be refreshed to retain a deterministic state. REF logic 326, for example, may indicate a location for refresh, and a type of refresh to perform. REF logic 326 may trigger self-refresh within memory device(s) 340 or execute external refreshes which can be referred to as auto refresh commands by sending refresh commands, or a combination. According to some examples, system 300 supports all bank refreshes as well as per bank refreshes. All bank refreshes cause the refreshing of banks within all memory device(s) 340 coupled in parallel. Per bank refreshes cause the refreshing of a specified bank within a specified memory device of memory device(s) 340. In some examples, controller 350 within memory device(s) 340 includes a REF logic 354 to apply refresh within memory device(s) 340. REF logic 354, for example, may generate internal operations to perform refresh in accordance with an external refresh received from memory controller 320. REF logic 354 may determine if a refresh is directed to memory device(s) 340 and determine what memory resources 360 to refresh in response to the command.

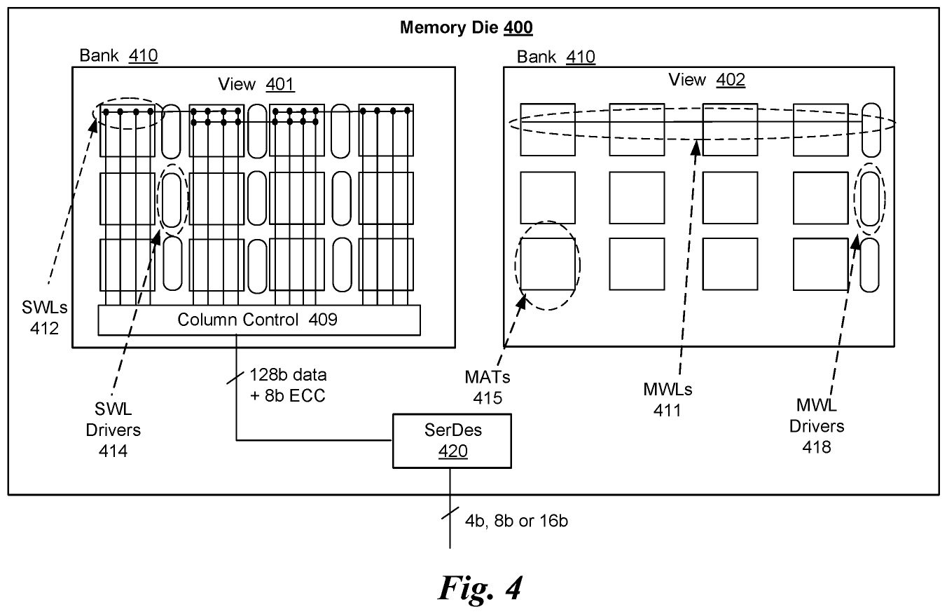

FIG. 4 illustrates an example memory die 400. In some examples, as shown in FIG. 4, two views, view 401 and view 402 are shown of a bank 410. Memory die 400, in some examples, may be DRAM memory die and bank 410 may represent one of a plurality of banks for the DRAM memory die. For these examples, each bank may have multiple small memory arrays or MATs that are depicted in views 401 and 402 as MATs 415. In addition, word-lines for bank 410 may have a hierarchy, where a main word-line (MWL) is segmented into multiple sub word-lines (SWLs). View 402 shows an example MWL 411 and view 401 shows an example of SWLs 412 corresponding to MWL 411.

According to some examples, as shown in FIG. 4, SWL drivers 414 may be located between MATs 415. For these examples, SWL drivers 414 may drive SWLs on both sides in a staggered manner. Also, view 402 depicts MWL drivers 418 to drive respective MWLs 411. A serializer/deserializer (SERDES) 420 may be arranged to enable 128b of data+8 ECC bits to be routed from a column control 409 of bank 410 to a memory channel interface using different channel widths, such as but not limited to a 4b channel width (x4), a 8b channel width (x8), or a 16b channel width (x16). Other combinations of data sizes and ECC bits may be implemented, as described below.

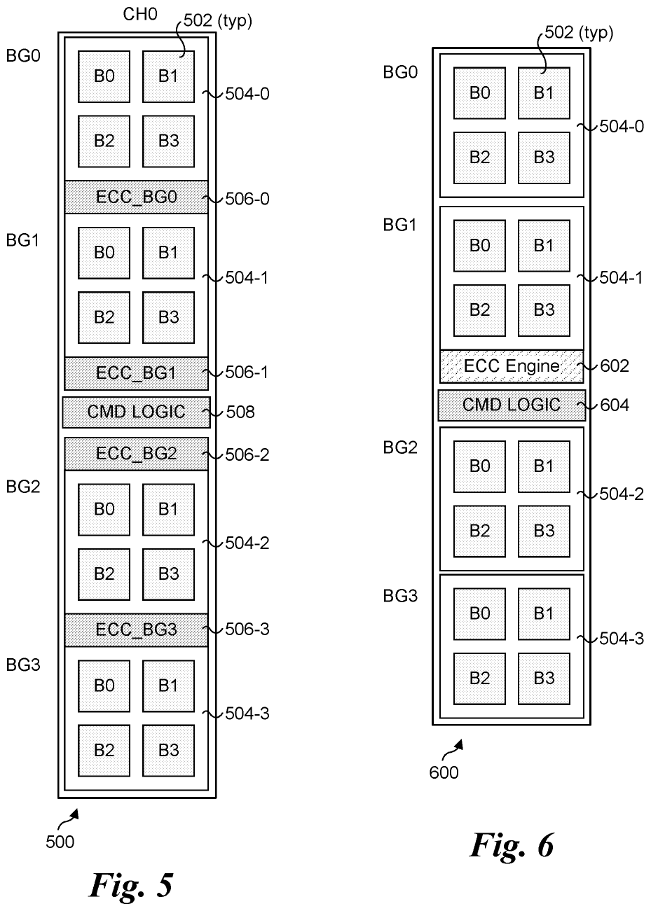

FIG. 5 shows a DRAM die 500 that implements a respective ECC engine per bank group, according to one embodiment. DRAM die 500 includes multiple banks 502 that are grouped in four bank groups 504-0, 504-1, 504-2, and 504-3 (also shows a BG0, BG1, BG2, and BG3). Each bank group has a respective ECC engine 504-0, 504-1, 504-2, and 504-3. DRAM die 500 also includes CMD logic 508.

Under the architecture employed by DRAM die 500, all ECC operations are performed by the DRAM die. The applicable ECC engine for a bank group computes ECC on write data before writing ECC and data to an array in one of the banks 502 in the bank group. The embodiment also computes ECC on reads and fixes any errors before sending data the read data to a (requesting) host. In one embodiment, the ECC engines employ either SEC (Single Error Correction) or SECDED (Single Error Correction and Double Error Correction) codes. If a partial write is received, then the DRAM will do an internal ‘read modify write’ operation. Employing an ECC engine per bank group enables concurrent operations to other bank groups.

FIG. 6 shows a DRAM die 600 the implements a single ECC engine across the bank groups. As with DRAM die 600, DRAM die 600 includes four bank groups 504-0, 504-1, 504-2, and 504-3, each having four banks 502. DRAM die 600 further includes an ECC engine 602 and CMD logic 604. Under the architecture employed by DRAM die 600, ECC engine 602 is primarily used for testing. For example, such testing might be performed during system integration or could be employed during system/platform boot or platform initialization operations.

In runtime, the ECC bits that are stored in the DRAM array are provided to the host. The host can provide much better Reliability, Availability and Serviceability (RAS) coverage as it combines data from multiple reads to a common ECC code. For example, in one embodiment, there is four ECC bits (4b) per 16B (bytes) of data the bank group arrays. Accordingly, if the fetch size is 32B (bytes) and DRAM has 8b ECC then only SEC coverage can be provided. Conversely, if the host uses 64B cachelines then it has access to 16b of ECC. This can provide SEC coverage along with a very high percentage of error detection rate. The host can also perform much faster ECC calculation as it is on a logic process thus reducing latency. Optionally, in one embodiment some of the ECC bits can also be traded off with metadata bits, thus allowing a more flexible solution depending on the usage model.

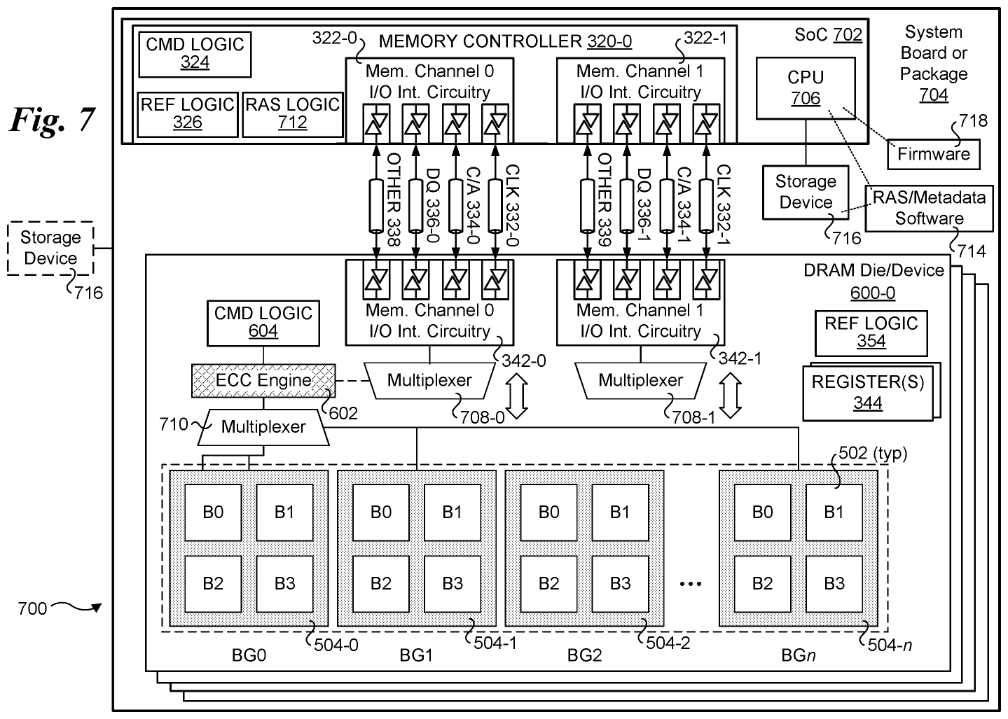

FIG. 7 shows an embodiment of a system 700 including an SoC 702 and a plurality of DRAM dies/devices 600 coupled to a system board or integrated in a package 704 (such as a multi-chip module or stacked die 3D structure as discussed below. SoC 702 includes a CPU 706 and one or more integrated memory controllers, such as depicted by a memory controller 320-0. Each memory controller includes one or more memory channels 322 (as depicted by memory channels 322-0 and 322-1), CMD logic 324, REF logic 326, and RAS logic 712. Similar to the memory channels described and illustrated in FIG. 3, each of memory channels 322-0 and 322-1 includes respective sets of signals and lines/buses, as depicted by CLK signals 332-0 and 332-1, C/A signals 334-0 and 334-1, DQ lines/buses 336-0 and 336-0, and optional other signals 338 and 339.

Each of the multiple memory dies/devices have a configuration similar to DRAM die/device 600-0, including memory channel I/O interface circuitry for one or more memory channels, as depicted by memory channel 0 I/O interface circuitry 342-0 and memory channel 1 I/O interface circuitry 342-1. DRAM die/device 600-0 includes n bank grounds 504-0, 504-1, 504-2 . . . 504-n (also labeled GB0, GB1, GB2 . . . GBn), each comprising four banks 502 in this example, where n is an integer of 4 or greater. Multiplexers 708-0 and 708-1 are representative of multiplexed circuitry that is used to couple the C/A signals and DQ lines/buses in the memory channel 0 and memory channel 1 I/O interface circuitry 342-0 and 342-1 to sets of bank groups and to individual banks within those bank groups. As will be recognized by those skilled in the art, the number of C/A signals and DQ lines on the I/O interfaces on the memory controller side are greater than on the I/O interfaces for the individual DRAM dies/devices, such that respective portions of those C/A signals and DQ lines will be coupled to respective DRAM dies/devices.

Each of DRAM die/device 600 includes an ECC engine 602, CMD logic 604, REF logic 354 and registers 344. ECC engine is coupled to a multiplexer 710, which is representative of multiplexed circuitry that is used to couple ECC engine to each of banks 502 across the bank groups. When operating in a first mode, ECC engine 602 performs testing operations to verify the integrity of the memory arrays in each of banks 502.

When operating in a second mode, the memory banks 502 are accessed in a similar manner to conventional Read and Write operations, except the ECC bits used for the test mode are repurposed as RAS bits and/or metabits that are made available to the host (e.g., SoC 702, which may also be referred to as a host processor). As described in further detail below RAS/Metadata software 714 running on one or more cores on CPU 706 may employ the RAS/metabits to perform RAS operations and (optionally, with the metabits) other operations. In the illustrated embodiment, RAS/metadata software 714 is stored in a storage device 716, which may be on a system board and coupled to an I/O port (not shown) on SoC 702 or may be internal or external to an SoC/stacked DRAM package. Also, RAS bits may be used to perform RAS operations using RAS logic 712 in memory controller 320-0.

A system or platform may also include firmware 718 that is executed on one or more cores of CPU 706 to boot/initialize the system/platform and to support various runtime operations. Generally, firmware 718 may be stored in the same storage device as the software (e.g., storage device 716), or in a separate storage device. In addition to RAS/Metadata software 714, the software on a system/platform will also include an operating system and one or more applications.

In one embodiment the mode of DRAM die/device 600-0 may be set by programming a mode register in registers 344. In one embodiment, CMD logic 604 interfaces with ECC engine 602 to report memory array test results to software and/or firmware running on CPU 706. For example, in some embodiments, the test mode operations may be performed during system boot via execution of firmware instructions used to initialize the system. Under another embodiment, a mode register may be programmed during system integration using a test apparatus.

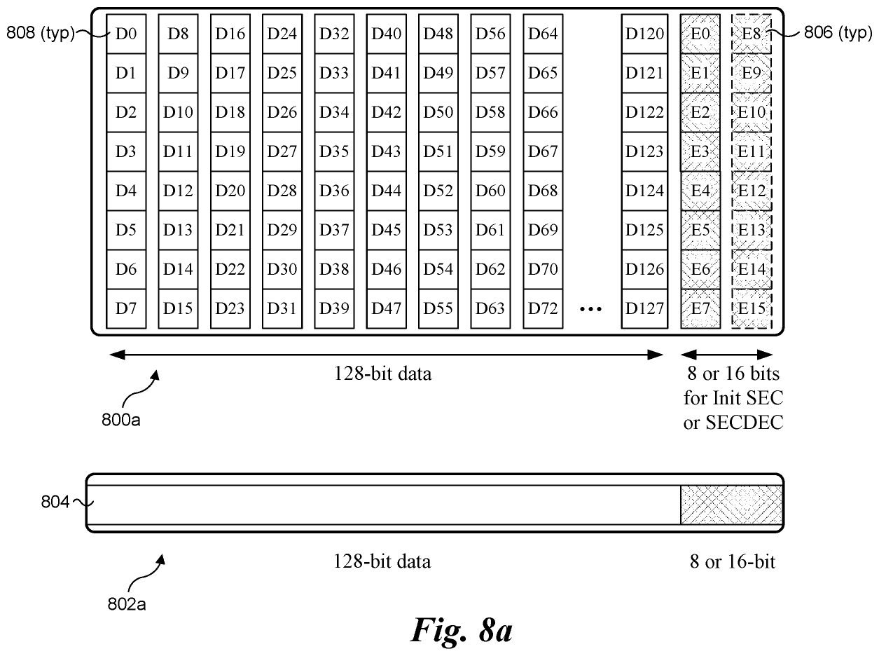

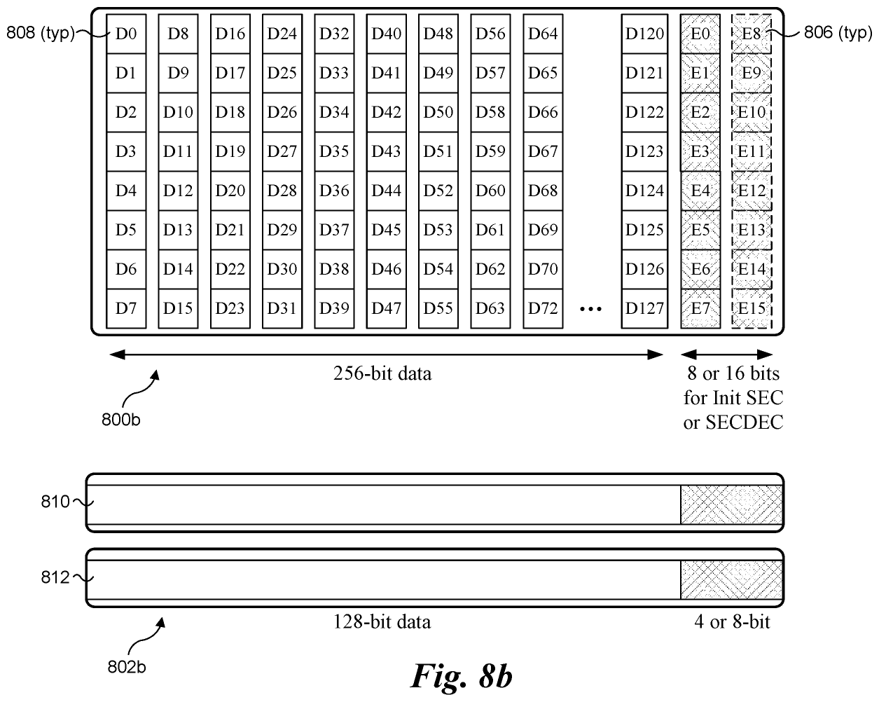

FIGS. 8a, 8b, 9, 10a, and 10b illustrate exemplary and non-limiting data/ECC bit configurations that may be implemented using the principles and teachings disclosed herein. For example, FIG. 8a shows a first configuration in which 8 or 16 bits are used as ECC bits 808 for 128 data bits 808. The upper diagram shows a logical representation 800a of the data and ECC bits, while the lower diagram shows a physical representation 802a where a sequence of 136 bits (128-bit data+8 ECC bits or 144 bits (128-bit data+16 ECC bits) are implemented for memory cells in an SWL 804. When used in the first mode (e.g., test and/or system integration), the ECC bits are labeled E0, E1, E2, etc. As illustrated and explained in further detail below, these same bits are labeled as RAS bits (e.g., R0, R1, R2, etc.) and/or Metabit (e.g., M0, M1, M2, etc.) when used by the host during runtime. When 8 ECC bits are available, SEC codes are used to detect SEC errors during test. When 16 ECC bits are available, both the ECC bits are encoded to detect both SEC and DEC errors.

FIG. 8b shows a second configuration including a logical representation 800b employing 8 or 16 ECC bits 806 for every 256 bits of data (bits) 808. As shown in physical representation 802b, the 256 bits of data are stored in two SWLs 810 and 812, each with either 4 or 8 ECC bits 806. In other embodiments that are not separately shown, an SWL may be configured for 64 bits of data or multiples of 64 bits of data other than 128 bits or 256 bits.

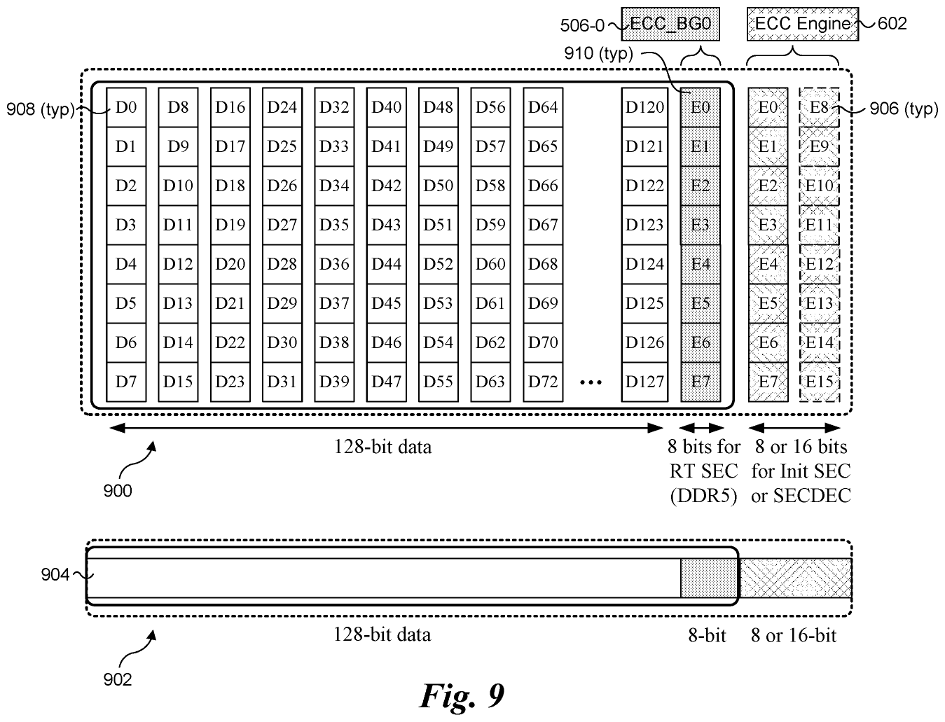

In some embodiments, a combination of the ECC approaches shown in FIGS. 5 and 6 discussed above are implemented. Examples of a logical representation 900 and physical representation 902 is shown for an SWL 904 in FIG. 9. In this example, for each SWL of 128-bits of data (bits) 908, there are 8 ECC bits 910 that are used by on-die ECC engine 506-0 during runtime, and 8 or 16 ECC bits 906 that are used for testing/integration when operating in the first mode (i.e., for testing during system/platform initialization (init) or system integration). For example, in one embodiment the approach shown in FIG. 9 supports the on-die ECC requirements defined in the DDR5 JEDEC specification. In the illustrated embodiment, the ECC bits 910 used for runtime are located before ECC bits 906 used for test/init/integration. In other embodiment (not shown), the order of these ECC bits is reversed.

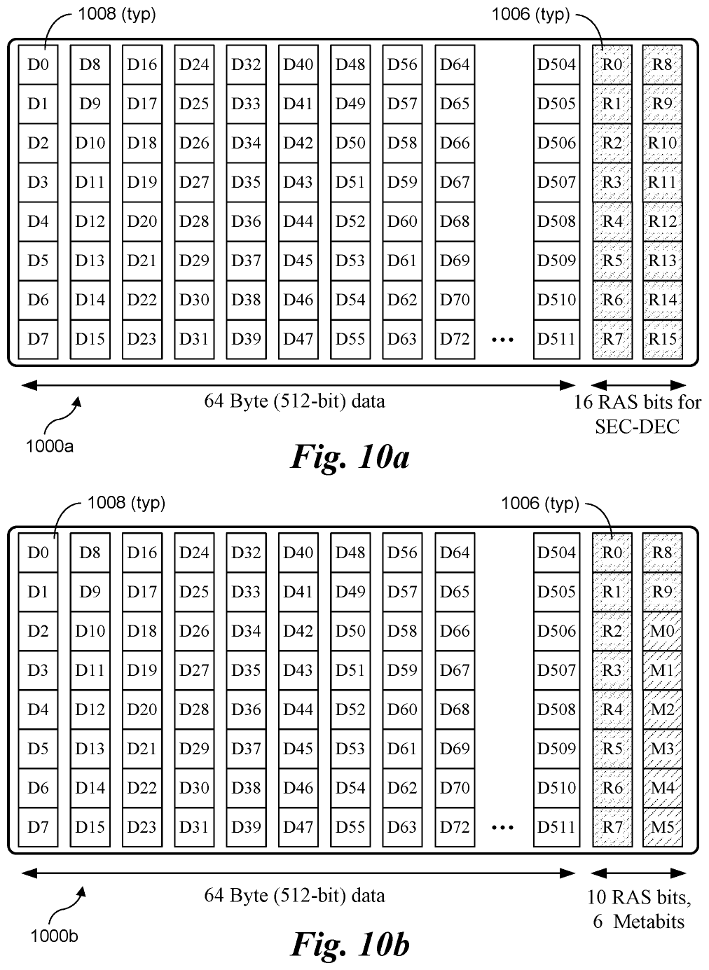

FIGS. 10a and 10b show two examples of the repurposed use of ECC bits 1006 during runtime. Under logical representations 1000a and 1000b there are 512 data bits 1008 comprising 64 Bytes of data, which is corresponds to the size of a memory cache line (or cacheline) under some processor architectures. In FIG. 10a, the 16 ECC bits 1006 are repurposed as 16 RAS bits R0, R1, R2 . . . R15 during runtime. These bits are passed to the host (e.g., SoC memory controller and/or SoC CPU) during the runtime operations. RAS logic in the memory controller and/or RAS logic implemented in software running on the SoC CPU/processor use the 16 RAS bits to perform RAS operations, such as SEC-DEC error detection.

As shown in FIG. 10b, the 16 ECC bits 1006 are repurposed as 10 RAS bits R0, R1, R2 . . . R9 and 6 metabits M0, M1, M2 . . . M5 during runtime. The RAS bits may be used to perform RAS-related operations. Meanwhile, the metabits may be employed by either the memory controller or software running on the host to perform various other functions, such as but not limited to poison detection, and two level memory (2LM) operations.

The configurations repurposed ECC bit configurations in FIGS. 10a and 10b are examples of different configurations that may be used. Generally, the split between RAS bits and metabits may vary, depending on the requirements of a particular implementation. Additionally, the logic used for such implementations may also vary. For example, in some embodiments the RAS-related operations are implemented by logic in the host memory controller while metabit-related operations are implemented in software executing on the host. It is also possible to have different functions implemented on the memory controller and in software for memory Reads and Writes. For example, in one embodiment in response to a request to read a cache line by the software, the memory controller will read and return two 32 Byte+8 RAS bits chunks and the software will employ the 16 RAS bits for the 62 Byte of data to verify the integrity of the data as they are received. For a memory Write of a cache line of data, the data will be forwarded from the software to the memory controller and the memory controller will generate the 8 RAS bits for each of 32 Byte chunks that are written to an applicable physical memory address on an applicable DRAM device. Under another embodiment, the 64 Bytes of data may be Read and Written by the memory controller as 128-bit+4 RAS bit chunks.

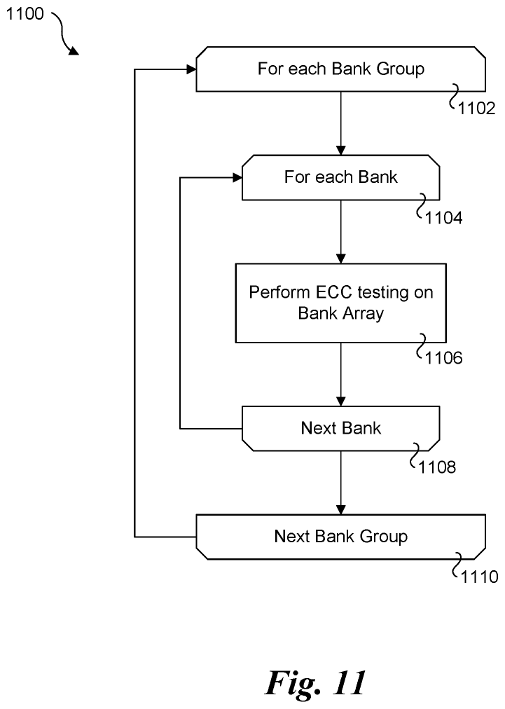

FIG. 11 shows a flowchart 1100 illustrating operations performed by the on-die ECC engine during system/platform initialization and/or integration, according to one embodiment. As show by the outer loop connecting start and end loop blocks 1102 and 1110 and the inner loop connection start and end loop blocks 1104 and 1108, the on-die ECC engine performs ECC testing on the bank array for each bank in the DRAM die in block 1106. Since this is done prior to runtime, there is no need to access banks in parallel, enabling a single on-die ECC engine to walk through all the bank arrays on the DRAM die.

In one embodiment, the ECC testing operations entail the following. First, all zeroes are written to all the cells in the rows for each bank. Next, data are written to the rows in the bank(s), followed by reading of the data. The ECC engine generates the ECC bits in conjunction with the Writes and then checks for data integrity for each Read using the ECC bits. Generally, these operations may be performed one bank at a time (e.g., clear with 0's, Write data rows, Read data rows) for the bank, may be sequenced across bank groups or across all banks in a DRAM die/device (e.g., clear bank group/all banks with 0's, Write data to banks in bank group/all banks, Read data from bank group/all banks), or a combination. The data to be written may comprise data generated using predetermined patterns and/or may be randomly generated.

For an integration test that will be separate from a boot sequence to be followed by runtime operations, the testing may be more comprehensive since the test period latency will generally be less relevant or irrelevant. For example, a test sequence during a system/platform boot might entail a single Write/Read test for each row (or each SWL), while an integration test might entail multiple Writes and Reads for each row (or each SWL).

Generally, the principles and teachings disclosed herein may be applied to various packages and configurations, including stacked die structures and packages, such as processor-in-memory (PIM) modules (also called compute on memory modules or compute near memory modules). PIMs may be used for various purposes but are particularly well-suited for memory-intensive workload such as but not limited to performing matrix mathematics and accumulation operations. In a PIM module (which are sometimes called PIM chips when the stacked die structures are integrated on the same chip), the processor or CPU and stacked memory structures are combined in the same chip or package.

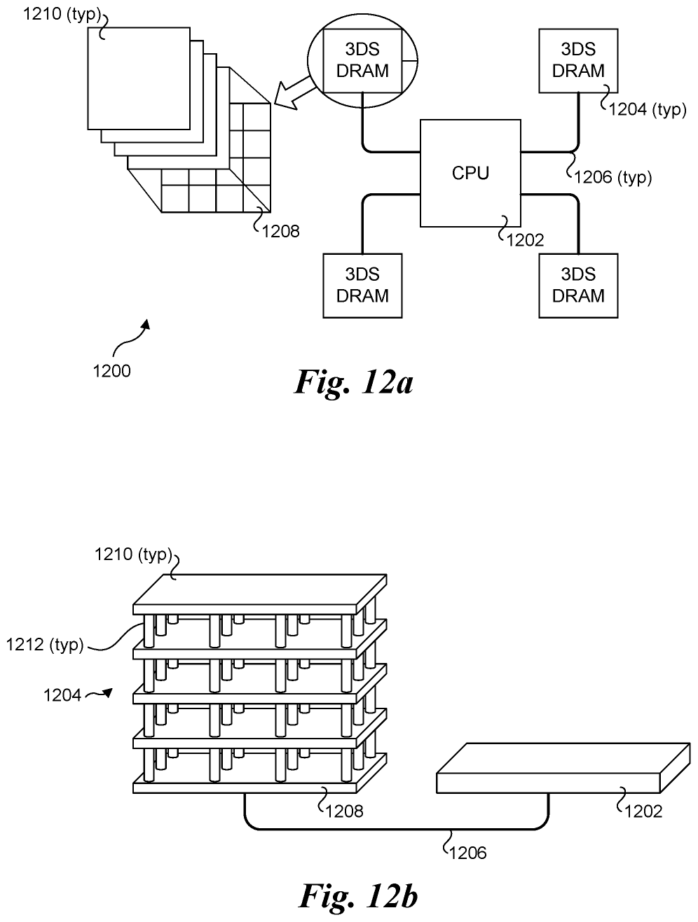

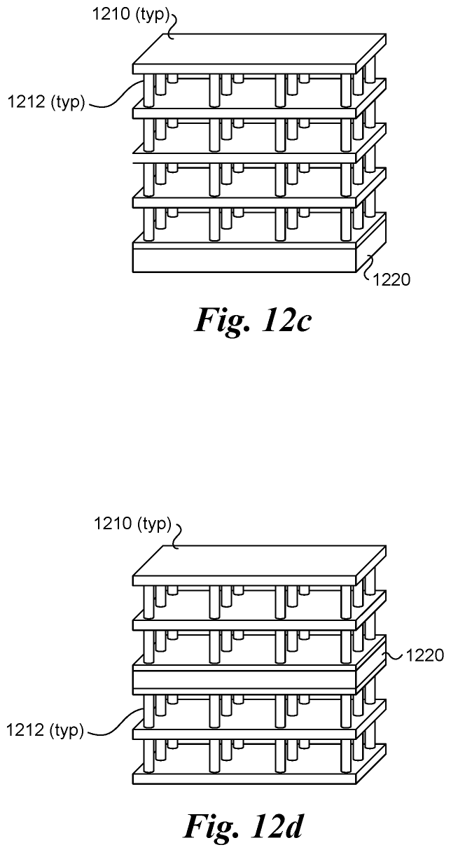

An example of a PIM module 1200 is shown in FIGS. 12a and 12b. PIM module 1200 includes a CPU 1202 coupled to 3DS (three dimensional stacked) DRAM 1204 via respective memory channels 1206, observing there may be multiple memory channels coupled between a CPU and a 3DS DRAM. As shown in the blow-up detail, a 3DS DRAM includes a logic layer comprising a logic die or compute die 1208 above which multiple DRAM dies 1210 are stacked. Logic die or compute die 1208 and DRAM dies 1210 are interconnected by TSVs 1212.

An aspect of PIM modules is that the logic layer may perform compute operations that are separate from the compute operations performed by the CPU, hence comprise a compute die. In some instances, the logic layer comprises a processor die or the like. For example, a system may be implemented using a 3D stacked structure similar to that shown in FIG. 12b, where compute die 1208 comprises an SoC with one or more compute elements (e.g., processor cores) and an integrated memory controller. In one embodiment, a portion of TSVs 1212 is used for memory controller I/O interface interconnects for one or more memory channels. The number and density of the TSV is much greater than shown in FIG. 12b, which shows a simplified representation of the 3D stacked structure of an exemplary PIM.

FIGS. 12c and 12d show an example of a CPU or XPU (Other Processing Unit) 1220 that is used in place of logic die or compute die 1208 without a separate CPU or XPU. Under the embodiment shown in FIG. 12c, multiple layers of DRAM dies 1210 are above CPU/XPU 1220. In the embodiment shown in FIG. 12d, one or more layers of DRAM dies 1210 are above and below CPU/XPU 1220.

In addition to systems with CPUs, the teaching and principles disclosed herein may be applied to Other Processing Units (collectively termed XPUs) including one or more of Graphic Processor Units (GPUs) or General Purpose GPUs (GP-GPUs), Tensor Processing Units (TPUs), Data Processing Units (DPUs), Infrastructure Processing Units (IPUs), Artificial Intelligence (AI) processors or AI inference units and/or other accelerators, FPGAs and/or other programmable logic (used for compute purposes), etc. While some of the diagrams herein show the use of CPUs, this is merely exemplary and non-limiting. Generally, any type of XPU may be used in place of a CPU or processor in the illustrated embodiments. Additionally, the term processor in the claims may refer to a CPU or an XPU.

In addition to 3D stacked structures with TSVs, other types of packaging may be used, such as multichip modules and packages using die-to-die or chiplet-to-chiplet interconnect structures. For instance, in one embodiment memory channels 1206 in FIGS. 12a and 12b are implemented using TSVs in a silicon die-to-die interconnect.

While various embodiments described herein use the term System-on-a-Chip or System-on-Chip (“SoC”) to describe a device or system having a processor and associated circuitry (e.g., I/O circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., 110 circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems, the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

Generally, various ECC codes/algorithms may be used to perform the ECC and RAS operations referenced herein using known techniques, with the particular codes/algorithms being outside the scope of this disclosure. Likewise, the metabits referenced herein may be used to support various known functions using known encoding schemes.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

As discussed above, various aspects of the embodiments herein may be facilitated by corresponding software and/or firmware components and applications, such as software and/or firmware executed by an embedded processor or the like. Thus, embodiments of this invention may be used as or to support a software program, software modules, firmware, and/or distributed software executed upon some form of processor, processing core or embedded logic a virtual machine running on a processor or core or otherwise implemented or realized upon or within a non-transitory computer-readable or machine-readable storage medium. A non-transitory computer-readable or machine-readable storage medium includes any mechanism for storing or transmitting information in a form readable by a machine (e.g., a computer). For example, a non-transitory computer-readable or machine-readable storage medium includes any mechanism that provides (i.e., stores and/or transmits) information in a form accessible by a computer or computing machine (e.g., computing device, electronic system, etc.), such as recordable/non-recordable media (e.g., read only memory (ROM), random access memory (RAM), magnetic disk storage media, optical storage media, flash memory devices, etc.). The content may be directly executable (“object” or “executable” form), source code, or difference code (“delta” or “patch” code). A non-transitory computer-readable or machine-readable storage medium may also include a storage or database from which content can be downloaded. The non-transitory computer-readable or machine-readable storage medium may also include a device or product having content stored thereon at a time of sale or delivery. Thus, delivering a device with stored content, or offering content for download over a communication medium may be understood as providing an article of manufacture comprising a non-transitory computer-readable or machine-readable storage medium with such content described herein.

Some operations and functions performed by various components described herein may be implemented by software running on a processing element, via embedded hardware or the like, or any combination of hardware and software. Such components may be implemented as software modules, hardware modules, special-purpose hardware (e.g., application specific hardware, ASICs, DSPs, etc.), embedded controllers, hardwired circuitry, hardware logic, etc. Software content (e.g., data, instructions, configuration information, etc.) may be provided via an article of manufacture including non-transitory computer-readable or machine-readable storage medium, which provides content that represents instructions that can be executed. The content may result in a computer performing various functions/operations described herein.

Italicized letters, such as ‘m’ are used to depict an integer number, and the use of a particular letter is not limited to particular embodiments. Moreover, the same letter may be used in separate claims to represent separate integer numbers, or different letters may be used. In addition, use of a particular letter in the detailed description may or may not match the letter used in a claim that pertains to the same subject matter in the detailed description.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A Dynamic Random Access Memory (DRAM) device comprising:
a plurality of bank groups, each bank group comprising multiple memory banks, each memory bank including an array of memory cells arranged in rows and columns;
memory channel input/output (I/O) circuitry for one or more memory channels, and
an error correction code (ECC) engine,
wherein the DRAM device is configured to operate in a first mode in which the ECC engine employs selected bits in the arrays of memory cells as ECC bits to perform ECC operations and to operate in a second mode under which the ECC bits are not employed for ECC operations by the ECC engine and made available for external use.

2. The DRAM device of claim 1, wherein the DRAM device is configured to be operatively coupled to memory channel I/O interface circuitry on a host processor and return, in response to a read request, read data and associated ECC bits to the memory channel IO interface circuitry when operating in the second mode.

3. The DRAM device of claim 2, wherein at least a portion of the ECC bits returned with the read data comprise metadata bits.

4. The DRAM device of claim 1, wherein the first mode is a test or integration mode, and the second mode is a runtime mode.

5. The DRAM device of claim 1, wherein the ECC engine is configured to implement at least one of Single Error Correction and Double Error Correction when operating in the first mode.

6. The DRAM device of claim 1, wherein the ECC engine is operatively coupleable to access each of the memory banks on the device and perform ECC testing for memory cells in the each of the memory banks.

7. The DRAM device of claim 1, wherein the DRAM device comprises a DRAM die.

8. The DRAM device of claim 7, wherein the DRAM die comprise a DRAM die in a three-dimensional structure comprising a plurality of stacked DRAM dies.

9. A system comprising:
a host including a memory controller having a plurality of memory channel interfaces having input/output (I/O) circuitry for a plurality of memory channels, each memory channel interface comprising a plurality of signal lines including one or more clock signal lines, a set of Command/Address (C/A) signal lines, and a plurality of DQ lines for read data and write data; and
a plurality of Dynamic Random Access Memory (DRAM) devices, each operatively coupled to one or more of the plurality of memory channel interfaces for the memory controller and including,
a plurality of bank groups, each bank group comprising multiple memory banks, each memory bank including an array of memory cells arranged in rows and columns; and
an error correction code (ECC) engine,
wherein the DRAM devices are configured to operate in a first mode in which the ECC engine employs selected bits in the arrays of memory cells as ECC bits to perform ECC operations and to operate in a second mode under which the ECC bits are not employed for ECC operations by the ECC engine and provided to the host.

10. The system of claim 9, wherein the plurality of DRAM devices comprises a plurality of DRAM dies that are stacked above, below, or both above and below a compute die including the memory controller.

11. The system of claim 10, wherein the compute die comprises a System on a Chip (SoC) or System-on-Package (SoP) having a die including a processor and on which the memory controller is integrated.

12. The system of claim 9, wherein the memory controller is integrated in a System on a Chip (SoC) comprising the host and including a processor, further comprising:
instructions, stored in the system, to enable, when executed on the processor, the system to,
receive, in response to a memory read operation, read data and a plurality of ECC bits that have been repurposed as at least one of Reliability, Serviceability, and Availability (RAS) bits and metadata bits; and
perform as least one of,
RAS operations employing the RAS bits; and
operations employing the metabits.

13. A method comprising:
operating a DRAM die in a first mode, the DRAM die comprising a plurality of bank groups, each bank group comprising multiple memory banks, each memory bank including an array of memory cells arranged in rows and columns, where during the first mode an error correction code (ECC) engine employs selected bits in the arrays of memory cells as ECC bits to perform ECC operations; and
operating the DRAM die in a second mode under which the ECC bits are not employed for ECC operations by the ECC engine and are made available for external use.

14. The method of claim 13, wherein the DRAM device is operatively coupled to memory channel input/output (I/O) interface circuitry on a host processor, further comprising:
receiving a read request from the host, and
in response to a read request,
reading data and associated ECC bits from one or more rows in a memory bank; and
returning the data and associated ECC bits to the host.

15. The method of claim 14, further comprising:
storing a respective set of ECC bits for each of a plurality of data units having a first size; and
returning m sets of ECC bits for a read request for data having a second size that is a multiple m of the first size.

16. The method of claim 15, further comprising:
employing ECC bits in the m sets of ECC bits to perform ECC operations on the data returned in response to the read request.

17. The method of claim 15, wherein the first size is 128 bits or 256 bits and respective set of ECC bits comprises 8 bits.

18. The method of claim 13, further comprising:
receiving a write request at the DRAM die, the write request comprising data having the second size;
writing the data as m data units having the first size to cells in an array of cells in a memory bank;
generating, for each of the m data units, a set of ECC bits; and
writing the ECC bits into cells in the array of cells associated with the m data units reserved for ECC bits.

19. The method of claim 13, wherein the first mode is a test mode, and the second mode is a runtime mode.

20. The method of claim 13, further comprising employing the ECC engine to implement at least one of Single Error Correction and Double Error Correction when operating in the first mode.
